(19) United States
(12) Patent Application Publication
(10) Pub. No.: US 2009/0246713 A1
(43) Pub. Date: Oct. 1, 2009

(54) OXYGEN-CONTAINING PLASMA FLASH PROCESS FOR REDUCED MICRO-LOADING EFFECT AND CD BIAS

(75) Inventors: Kelvin Zin, Peabody, MA (US); Masaru Nishino, Cambridge, MA (US)

Correspondence Address: Tokyo Electron U.S. Holdings, Inc., 4350 West Chandler Blvd., Suite 10/11, Chandler, AZ, 85226, US

(73) Assignee: TOKYO ELECTRON LIMITED, Tokyo (JP)

(21) Appl. No.: 12/058,958

(22) Filed: Mar. 31, 2008

(51) Int. Cl. G03F 7/26

(52) U.S. Cl. 430/323

(57) ABSTRACT

A method for transferring a feature pattern to a thin film on a substrate using a hard mask layer is described. The method comprises exposing the substrate to an oxygen-containing flash process after the feature pattern is transferred to the hard mask layer and before the feature pattern is transferred to the thin film.

### BACKGROUND OF THE INVENTION

1. Field of Invention

The invention relates to a method for pattern etching a substrate, and more particularly to a method for pattern etching a substrate while reducing the effects of micro-loading and critical dimension (CD) bias.

2. Description of Related Art

Typically, during fabrication of integrated circuits (ICs), semiconductor production equipment utilize a (dry) plasma etch process to remove or etch material along fine lines or within vias or contacts patterned on a semiconductor substrate. The success of the plasma etch process requires that the etch chemistry includes chemical reactants suitable for selectively etching one material while substantially not etching another material. For example, on a semiconductor substrate, a pattern formed in a protective layer can be transferred to an underlying layer of a selected material utilizing a plasma etching process. The protective layer can comprise a radiation-sensitive layer, such as a photo-resist layer, having a pattern formed therein using a lithographic process. In order to pattern finer features in the lithographic layer using conventional lithography techniques, multi-layer masks can be implemented. For example, the multi-layer mask may include a bilayer mask or trilayer mask including one or more soft mask layers, or one or more hard mask layers, or a combination thereof. With the inclusion of a second or third layer, the uppermost lithographic layer may be thinner than the thickness customarily chosen to withstand the subsequent dry etching process(es) and, therefore, using conventional lithography techniques, finer features may be formed in the thinner lithographic layer. Thereafter, the finer feature formed in the lithographic layer may be transferred to the underlying second or third layers using a dry development process, such as a dry etching process. Once the pattern is established in the multi-layer mask, the pattern is transferred to the underlying layers using one or more etching processes. Examples of such an etching process include reactive ion etching (RIE), which is in essence an ion activated chemical etching process. However, although RIE has been in use for decades, its maturity is accompanied by several issues including, among other things, feature-shape loading effects (i.e., micro loading) and critical dimension (CD) control. A loading effect is generally used to describe an etching process having an etch rate that depends upon the exposed area. Local variations in the pattern density of the pattern being transferred using the etching process can cause local variations in the etch rate due to local depletion of the reactive species and this effect is referred to as micro-loading. It is essential that the micro-loading effect is reduced in order to mitigate RIE lag. Additionally, it is essential that a critical dimension (CD) for the multi-layer mask is preserved during pattern transfer such that the CD bias is minimal, i.e., the CD bias is the difference between the initial CD for the pattern in the multi-layer mask and the final CD for the pattern in the underlying layer(s). Further, if a CD bias is unavoidable, it is essential that the CD bias is uniformly maintained across the substrate. Further yet, if a CD bias is unavoidable, it is essential that the offset in CD bias between dense features (e.g., closely spaced features) and isolated features (e.g., widely spaced features) is minimal.

### SUMMARY OF THE INVENTION

The invention relates to a method for transferring a feature pattern to a substrate.

The invention also relates to a method for transferring a feature pattern to a substrate while reducing the effects of micro-loading and critical dimension (CD) bias.

According to one embodiment, a method, and computer readable medium, for transferring a feature pattern to a thin film on a substrate using a hard mask layer is described. The method comprises exposing the substrate to an oxygen-containing flash process after the feature pattern is transferred to the hard mask layer and before the feature pattern is transferred to the thin film.

According to another embodiment, a method of transferring a pattern to a substrate is described. The method comprises: disposing a substrate comprising a multi-layer mask overlying a thin film in a plasma processing system, wherein the multi-layer mask comprises at least a lithographic layer and a hard mask layer; forming a feature pattern in the lithographic layer using a lithographic process; transferring the feature pattern in the lithographic layer to the remaining layers of the multi-layer mask including the hard mask layer using one or more etching processes; exposing the feature pattern in the hard mask layer to an oxygen-containing flash process in order to remove residue from the feature pattern formed during the transferring of the feature pattern to the hard mask layer; and transferring the feature pattern in the hard mask layer to the thin film following the exposing of the feature pattern in the hard mask layer to the oxygen-containing flash process.

### BRIEF DESCRIPTION OF THE DRAWINGS

In the accompanying drawings:

FIGS. 1A through 1D illustrate a schematic representation of a procedure for etching a feature in a substrate according to an embodiment;

FIG. 2 provides a flow chart illustrating a method of etching a feature in a substrate according to an embodiment;

FIG. 3 shows a schematic representation of a processing system according to an embodiment;

FIG. 4 shows a schematic representation of a processing system according to another embodiment;

FIG. 5 shows a schematic representation of a processing system according to another embodiment;

FIG. 6 shows a schematic representation of a processing system according to another embodiment;

FIG. 7 shows a schematic representation of a processing system according to another embodiment;

FIG. 8 shows a schematic representation of a processing system according to another embodiment;

FIG. 9 shows a schematic representation of a processing system according to another embodiment; and

FIG. 10 illustrates several different feature patterns.

### DETAILED DESCRIPTION OF SEVERAL EMBODIMENTS

In the following description, for purposes of explanation and not limitation, specific details are set forth, such as a particular geometry of a processing system, descriptions of various components and processes used therein. However, it should be understood that the invention may be practiced in other embodiments that depart from these specific details.

In material processing methodologies, plasma is often utilized to create and assist surface chemistry on a substrate to facilitate the removal of material from the substrate or to facilitate film forming reactions for depositing material on the substrate. During the etching of a substrate, plasma may be utilized to create reactive chemical species that are suitable for reacting with the certain materials on the surface of a substrate. Furthermore, during the etching of a substrate, plasma may be utilized to create charged species that are useful for delivering energy to surface reactions on the substrate.

According to one example, pattern etching comprises the application of a lithographic layer, such as a thin layer of radiation-sensitive material (e.g., photo-resist), to an upper surface of a substrate that is subsequently patterned in order to provide a mask for transferring this pattern to the underlying thin film on the substrate during etching. The patterning of the radiation-sensitive material generally involves exposure of the lithographic layer to a geometric pattern of electromagnetic (EM) radiation using, for example, a micro-lithography system, followed by the removal of the irradiated regions of the radiation-sensitive material (as in the case of positive photo-resist), or non-irradiated regions (as in the case of negative resist) using a developing solvent.

In order to pattern thinner features in the lithographic layer using conventional lithography techniques, multi-layer masks can be implemented. For example, the multi-layer mask may include a bilayer mask or trilayer mask. With the inclusion of a second or third layer, the uppermost lithographic layer may be thinner than the thickness customarily chosen to withstand the subsequent dry etching process(es) and, therefore, using conventional lithography techniques, finer features may be formed in the thinner lithographic layer. Thereafter, the finer feature formed in the lithographic layer may be transferred to the underlying second or third layers using a dry development process, such as a dry etching process. However, there still exists a need to produce even finer features in the multi-layer mask.

Additionally, as described above, micro-loading effects continue to be an issue with etching processes during pattern transfer. As a result, RIE lag occurs, wherein dense features etch at a slower rate than isolated features.

Furthermore, during pattern transfer, undulations or variations in the edge profile of the pattern as well as variations in pattern dimension, can be propagated in to the underlying layers, such as the second mask layer, the third mask layer, etc., in a multi-layer mask. These undulations may be referred to as edge roughness or line edge roughness (LER). Edge roughness may arise due to damage to the layer of radiation-sensitive material. During the application of the radiation-sensitive material, the post-application bake (PAB), the exposure step, the post-exposure bake (PEB), or the wet developing step, or any combination thereof, the radiation-sensitive material may be damaged. Furthermore, damage may occur during the initial phases of the ARC layer etch, hard mask etch, or thin film etch.

Hence, there still exists a need to improve micro-loading effects (or reduce RIE lag) and correct for pattern deficiencies in the lithographic layer, such as edge roughness. During pattern transfer, conventional process chemistries fail to reduce RIE lag, while reducing the CD and reducing edge roughness.

Therefore, according to an embodiment, a method for transferring a feature pattern to a thin film on a substrate using a hard mask layer is described. The method comprises exposing the substrate to an oxygen-containing flash process after the feature pattern is transferred to the hard mask layer and before the feature pattern is transferred to the thin film. The inventors have observed that the insertion of the flash process between the patterning of the hard mask layer and the patterning of the underlying thin film can reduce RIE lag, among other things.

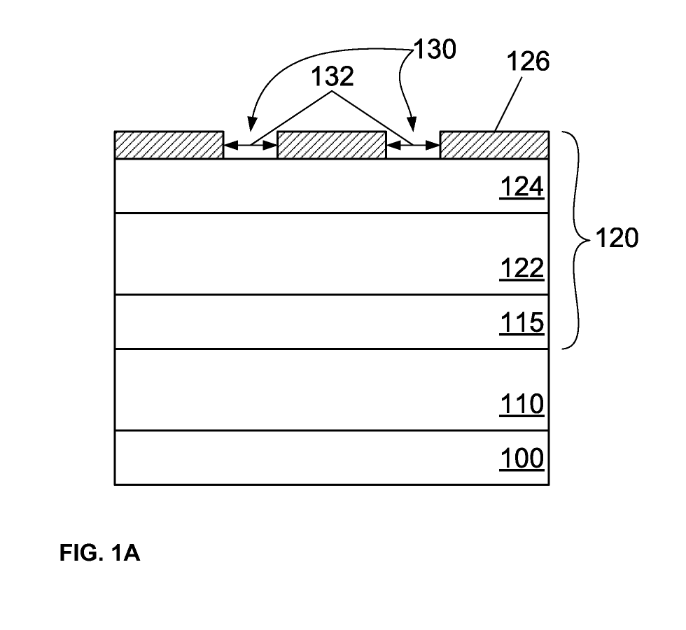

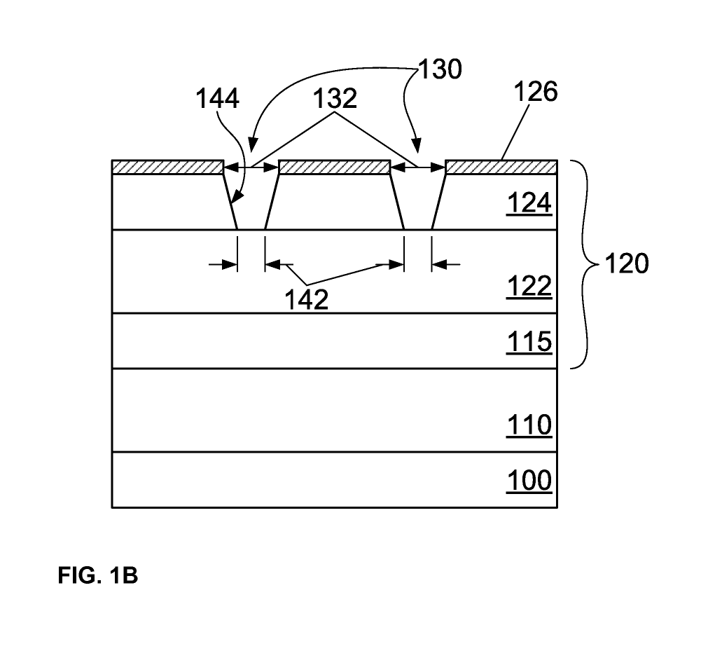

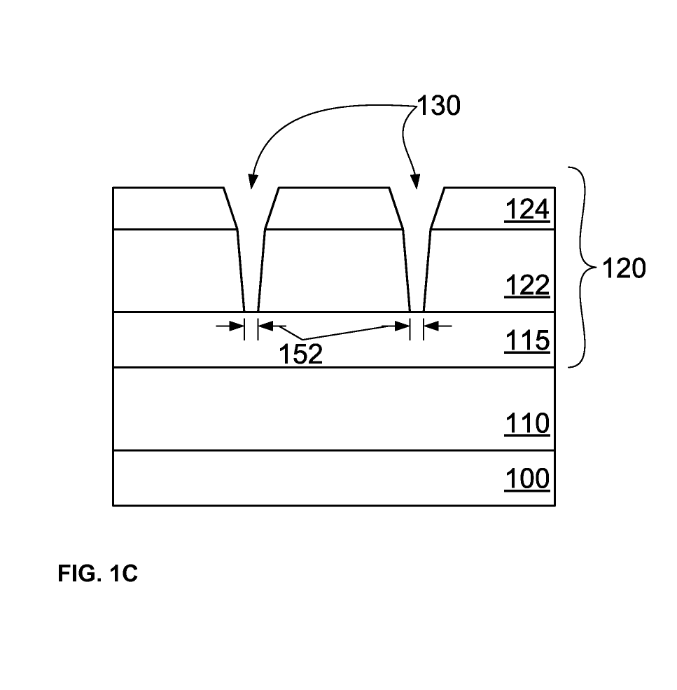

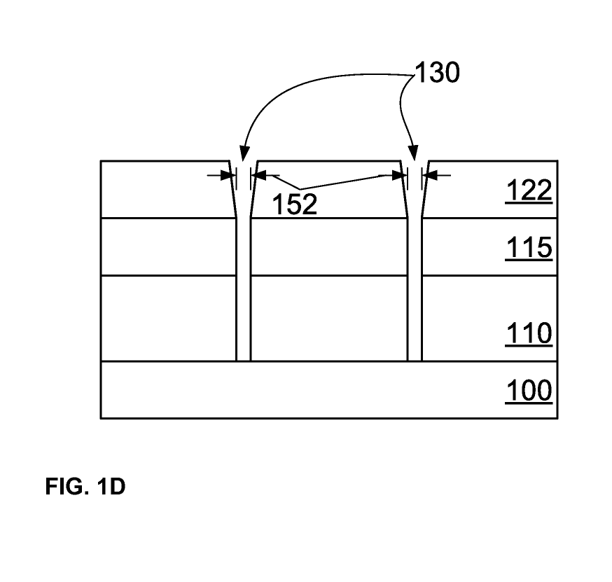

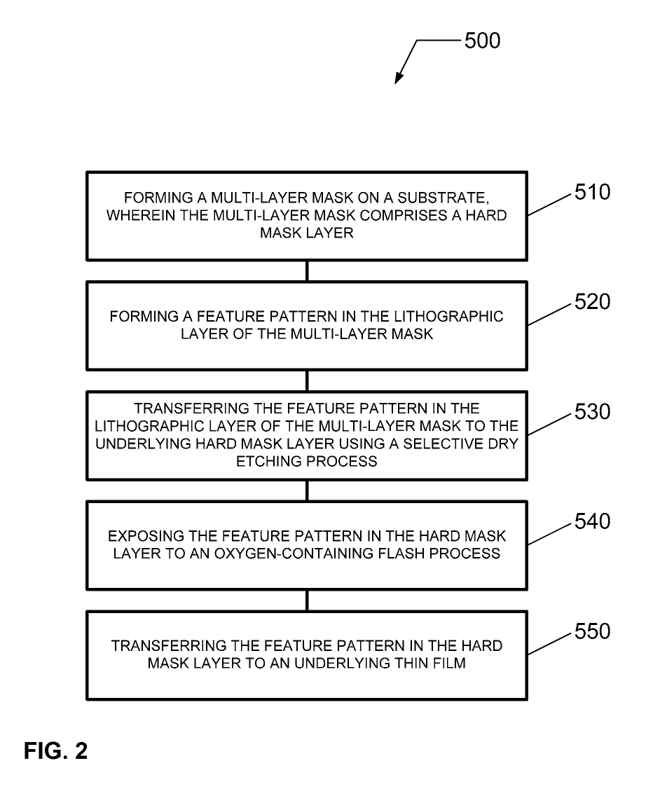

According to another embodiment, a method for transferring a feature pattern to a thin film on a substrate is schematically illustrated in FIGS. 1A through 1D, and is illustrated in a flow chart 500 in FIG. 2. The method begins in 510 with forming a multi-layer mask 120 on a thin film 110, to which a pattern is to be transferred, upon substrate 100. The multi-layer mask 120 comprises a lithographic layer 126, an optional second mask layer 124, an optional third mask layer 122, and a hard mask layer 115. Other layers may be disposed between the thin film 110 and the underlying substrate 100.

The substrate 100 may comprise a semiconductor substrate, a wafer, a flat panel display or a liquid crystal display.

The thin film 110 may comprise a conductive layer, a non-conductive layer, or a semi-conductive layer. For instance, the thin film 110 may include a material layer comprising a metal, metal oxide, metal nitride, metal oxynitride, metal silicate, metal silicide, silicon, poly-crystalline silicon (poly-silicon), doped silicon, silicon dioxide, silicon nitride, silicon carbide, or silicon oxynitride, etc. Additionally, for instance, the thin film 110 may comprise a low dielectric constant (i.e., low-k) or ultra-low dielectric constant (i.e., ultra-low-k) dielectric layer having a nominal dielectric constant value less than the dielectric constant of SiO₂, which is approximately 4 (e.g., the dielectric constant for thermal silicon dioxide can range from 3.8 to 3.9). More specifically, the thin film 110 may have a dielectric constant of less than 3.7, or a dielectric constant ranging from 1.6 to 3.7.

These dielectric layers may include at least one of an organic, inorganic, or inorganic-organic hybrid material. Additionally, these dielectric layers may be porous or non-porous.

For example, these dielectric layers may include an inorganic, silicate-based material, such as carbon doped silicon oxide (or organo siloxane), deposited using CVD techniques. Examples of such films include Black Diamond® CVD organosilicate glass (OSG) films commercially available from Applied Materials, Inc., or Coral® CVD films commercially available from Novellus Systems, Inc.

Alternatively, these dielectric layers may include porous inorganic-organic hybrid films comprised of a single-phase, such as a silicon oxide-based matrix having CH₃ bonds that hinder full densification of the film during a curing or deposition process to create small voids (or pores). Still alternatively, these dielectric layers may include porous inorganic-organic hybrid films comprised of at least two phases, such as a carbon-doped silicon oxide-based matrix having pores of organic material (e.g., porogen) that is decomposed and evaporated during a curing process.

Still alternatively, these dielectric layers may include an inorganic, silicate-based material, such as hydrogen silsesquioxane (HSQ) or methyl silsesquioxane (MSQ), deposited using SOD (spin-on dielectric) techniques. Examples of such films include FOx® HSQ commercially available from Dow Corning, XLK porous HSQ commercially available from Dow Corning, and JSR LKD-5109 commercially available from JSR Microelectronics.

Still alternatively, these dielectric layers can comprise an organic material deposited using SOD techniques. Examples of such films include SiLK-I, SiLK-J, SiLK-H, SiLK-D, and porous SiLK® semiconductor dielectric resins commercially available from Dow Chemical, and GX-3™, and GX-3P™ semiconductor dielectric resins commercially available from Honeywell.

The thin film 110 can be formed using a vapor deposition technique, such as chemical vapor deposition (CVD), plasma enhanced CVD (PECVD), atomic layer deposition (ALD), plasma enhanced ALD (PEALD), physical vapor deposition (PVD), or ionized PVD (iPVD), or a spin-on technique, such as those offered in the Clean Track ACT 8 SOD (spin-on dielectric), ACT 12 SOD, and Lithius coating systems commercially available from Tokyo Electron Limited (TEL) (Tokyo, Japan). The Clean Track ACT 8 (200 mm), ACT 12 (300 mm), and Lithius (300 mm) coating systems provide coat, bake, and cure tools for SOD materials. The track system can be configured for processing substrate sizes of 100 mm, 200 mm, 300 mm, and greater. Other systems and methods for forming a thin film on a substrate are well known to those skilled in the art of both spin-on technology and vapor deposition technology.

The lithographic layer 126 may comprise a layer of radiation-sensitive material, such as photo-resist. The photo-resist layer may comprise 248 nm (nanometer) resists, 193 nm resists, 157 nm resists, EUV (extreme ultraviolet) resists, or electron beam sensitive resist. The photo-resist layer can be formed using a track system. For example, the track system can comprise a Clean Track ACT 8, ACT 12, or Lithius resist coating and developing system commercially available from Tokyo Electron Limited (TEL). Other systems and methods for forming a photo-resist layer on a substrate are well known to those skilled in the art of spin-on resist technology.

The optional second mask layer 124 can comprise an anti-reflective coating (ARC) layer, such as a silicon-containing ARC layer. For example, the optional second mask layer 124 may comprise a silicon-containing ARC commercially available as Sepr-Shb Aseries SiARC from Shin Etsu Chemical Co., Ltd. The optional second mask layer 124 may, for example, be applied using spin coating technology, or a vapor deposition process.

The optional third mask layer 122 may comprise an inorganic layer or an organic layer. For example, the optional third mask layer 122 may comprise an organic planarization layer (OPL). The OPL can include a photo-sensitive organic polymer or an etch type organic compound. For instance, the photo-sensitive organic polymer may be polyacrylate resin, epoxy resin, phenol resin, polyamide resin, polyimide resin, unsaturated polyester resin, polyphenylenether resin, polyphenylenesulfide resin, or benzocyclobutene (BCB). These materials may be formed using spin-on techniques.

The hard mask layer 115 may comprise an oxide, a nitride, a carbide, an oxynitride, or a carbonitride. The hard mask layer may comprise a silicon-containing film, such as silicon oxide, silicon nitride or silicon oxynitride. The silicon oxide films contain silicon (Si) and oxygen (O), for example as SiOₓ, the silicon nitride films contain Si and nitrogen (N), for example as SiNₓ, and the silicon oxynitride films contain Si, N and O, for example as SiNₓO_{y}. The silicon oxide based films can, in addition to Si and O, further contain carbon (C), hydrogen (H), or both C and H. Additionally, the silicon nitride based films can, in addition to Si and N, further contain C, H, or both C and H. Furthermore, the silicon oxynitride based films can, in addition to Si, N and O, further contain C, H, or both C and H. Alternatively, the hard mask layer 115 may comprise amorphous carbon.

The hard mask layer 115 may, for example, be applied using a vapor deposition process, such as CVD, PECVD, ALD, PEALD, etc. Alternatively, the hard mask layer may, for example, be applied by depositing a silicon-containing film and exposing the silicon-containing film to an oxidation process, or a nitridation process, or both.

The hard mask layer 115 may further serve as a planarization stop layer, such as a chemical-mechanical planarization (CMP) stop layer. For example, when the feature pattern 130 is formed in the underlying thin film 110, it may be filled with metal and may be planarized using a CMP process, wherein the CMP process stops on the remaining hard mask layer 115.

In 520 and as shown in FIG. 1A, a feature pattern is 130 is formed in the lithographic layer 126 of the multi-layer mask 120. The lithographic layer 126 is imaged with an image pattern. Therein, the lithographic layer 126 is exposed to EM radiation through a reticle in a dry or wet photo-lithography system. The image pattern can be formed using any suitable conventional stepping lithographic system, or scanning lithographic system. For example, the photo-lithographic system may be commercially available from ASML Netherlands B.V. (De Run 6501, 5504 DR Veldhoven, The Netherlands), or Canon USA, Inc., Semiconductor Equipment Division (3300 North First Street, San Jose, Calif. 95134). Although photo-lithography is described above, other techniques may be used to form the image pattern in the lithographic layer. Other techniques may include direct-write or non-direct write techniques including electron beam patterning systems.

Thereafter, the image pattern is developed in the lithographic layer 126 to form feature pattern 130 having a first critical dimension (CD) 132. The developing process can include exposing the substrate to a developing solvent in a developing system, such as a track system. For example, the track system can comprise a Clean Track ACT 8, ACT 12, or Lithius resist coating and developing system commercially available from Tokyo Electron Limited (TEL).

In 530 and as shown in FIG. 1B, the feature pattern 130 is transferred from the lithographic layer 126 to the multi-layer mask 120, including the underlying hard mask layer 115. The transfer of the feature pattern 130 in the lithographic layer 126 to the remaining layers of the multi-layer mask 120 may be performed using one or more etching processes. The one or more etching processes may include any combination of wet or dry etching processes. The one or more etching processes may include one or more dry plasma etching processes. Each dry plasma etching process may comprise introducing a process gas to the plasma processing system according to a process recipe, forming plasma from the process gas in the plasma processing system according to the process recipe, and exposing the substrate to the plasma.

The feature pattern 130 may be transferred to the optional second mask layer 124, such as an ARC layer, using a first dry plasma etching process. For example, the first dry plasma etching process can comprise establishing a process recipe, introducing a process gas comprising an optional non-polymerizing gas and a polymerizing gas to a plasma processing system according to the process recipe, forming plasma from the process gas in the plasma processing system according to the process recipe, and exposing the substrate having the optional second mask layer 124 to the plasma.

The optional non-polymerizing gas can comprise an inert gas. Alternatively, the optional non-polymerizing gas can comprise a noble gas. Alternatively yet, the optional non-polymerizing gas can comprise argon (Ar).

The polymerizing gas can comprise at least one CₓF_{y}H_{z}-containing gas, wherein x and y are integers greater than or equal to unity and z is an integer greater than or equal to zero. The CₓF_{y}H_{z}-containing gas may include any gas containing carbon (C) and fluorine (F) (e.g., a fluorocarbon gas), or any gas containing C, F and hydrogen (H) (e.g., a hydrofluorocarbon gas). For example, the fluorocarbon gas may include CF₄, C₃F₆, C₄F₆, C₄F₈, or C₅F₈, or a combination of two or more thereof. Additionally, for example, the hydrofluorocarbon gas may include introducing trifluoromethane (CHF₃), or difluoromethane (CH₂F₂), or both.

For example, the first dry plasma etching process may include a process that utilizes plasma formed from a process gas containing CF₄ and CHF₃.

As shown in FIG. 1B, during the pattern transfer to the optional second mask layer 124, the first CD 132 for the feature pattern 130 in the lithographic layer 126 may be reduced to a second CD 142 in the optional second mask layer 124. When forming plasma from the process gas, a process recipe may be selected to cause a reduction from the first CD 132 in the lithographic layer 126 to the second CD 142 in the optional second mask layer 124. For example, the process condition can include: (1) selecting a ratio between an amount of the optional non-polymerizing gas and an amount of the polymerizing gas; (2) selecting a process pressure and one or more power levels for forming plasma; and (3) selecting an etch time.

Alternatively, during the pattern transfer to the optional second mask layer 124, the second CD 142 in the optional second mask layer 124 may be maintained as substantially the same as the first CD 132 for the feature pattern 130 in the lithographic layer 126. For example, once the feature pattern 130 extends through the thickness of the optional second mask layer 124, the etch time may be extended in order to reduce the amount of difference between the first CD 132 and the second CD 142.

As shown in FIG. 1C, the feature pattern 130 having second CD 142 formed in the optional second mask layer 124 may be transferred to the underlying optional third mask layer 122 to form a third CD 152 in the optional third mask layer 122 using one or more etching processes. The third CD 152 can be substantially the same as the second CD 142, or it may be less than the second CD 142 as illustrated in FIG. 1C. The one or more etching processes may include dry plasma etching processes or dry non-plasma etching processes. For example, the one or more etching processes may include a second dry plasma etching process that utilizes plasma formed from a process gas containing CO or CO₂, or both, and an optional gas including N₂ and/or a noble gas.

As shown in FIG. 1D, the feature pattern 130 having third CD 152 formed in the optional third mask layer 122 can be transferred to the underlying hard mask layer 115 using one or more selective etching processes. For example, the one or more selective etching processes may include a selective dry plasma etching process.

The selective dry plasma etching process may comprise selectively etching the hard mask layer 115 relative to the underlying thin film 110 using a polymerizing process chemistry. The use of the polymerizing process chemistry can comprise establishing a process recipe, introducing a process gas comprising at least one CₓF_{y}H_{z}-containing gas and an optional noble gas to a plasma processing system according to the process recipe (wherein x and y are integers greater than or equal to unity and z is an integer greater than or equal to zero), setting a chamber pressure in the plasma processing system, forming plasma from the process gas in the plasma processing system according to the process recipe, and exposing the substrate having the hard mask layer 115 to the plasma. For example, the process gas may comprise C₄F₈ and Ar.

The inventors have observed that, when etching the hard mask layer 115 using such a process gas, relatively high etch selectivity between the hard mask layer 115 and the underlying thin film 110 may be achieved; however, residue may form due to the polymerizing nature of the etch process. The inventors have further observed that if the residue is not removed, then adverse process effects may result as described above when the feature pattern 130 is transferred to the underlying thin film 110. For example, the inventors believe that (polymer) residue, resulting from the selective etching of the hard mask layer 115, contributes to RIE lag.

Therefore, in 540, the feature pattern 130 formed in the hard mask layer 130 is exposed to an oxygen-containing flash process. The oxygen-containing flash process comprises introducing an oxygen-containing gas to a plasma processing system, setting a flash chamber pressure in the plasma processing system, and forming plasma from the oxygen-containing gas. The oxygen-containing gas may comprise O₂, CO, CO₂, NO, NO₂, or N₂O, or any combination of two or more thereof. For example, the oxygen-containing gas may comprise CO₂.

The oxygen-containing flash process may further comprise introducing a noble gas to the plasma processing system. Additionally, the setting of the flash chamber pressure may comprise setting a pressure ranging from about 10 mtorr to about 20 mtorr. Furthermore, the oxygen-containing flash process may comprise setting a first power level for a first radio frequency (RF) signal applied to a lower electrode within a substrate holder for supporting the substrate, and setting a second power level for a second RF signal applied to an upper electrode opposing the lower electrode above the substrate.

In 550 and as shown in FIG. 1D, the feature pattern 130 having third CD 152 formed in the hard mask layer 115 can be transferred to the underlying thin film 110 using one or more etching processes. The one or more etching processes may include any combination of wet or dry etching processes. The dry etching processes may include dry plasma etching processes or dry non-plasma etching processes. For example, the one or more etching processes may include a dry plasma etching process that utilizes plasma formed from a process gas containing CF₄.

Thereafter, one or more ashing, stripping, and/or cleaning processes may be performed to remove residual material from the lithographic layer 126, residual material from the optional second mask layer 124, residual material from the optional third mask layer 122, post-etch residue, or post-ash residue, or any combination of two or more thereof.

The feature pattern 130 formed in the thin film 110 may include a via structure, a contact structure, or a trench structure, or any combination of two or more thereof. For example, the feature pattern 130 may include a trench-via structure, such as a dual damascene structure. The series of process steps may be performed one or more times to achieve the desired structure. For example, when preparing a trench-via structure, the series of steps may be modified to follow a conventional dual damascene process flow. However, when the respective trench or via pattern is transferred into the hard mask layer, the feature pattern may be exposed to the oxygen-containing flash process prior to transferring the respective feature pattern to the underlying thin film.

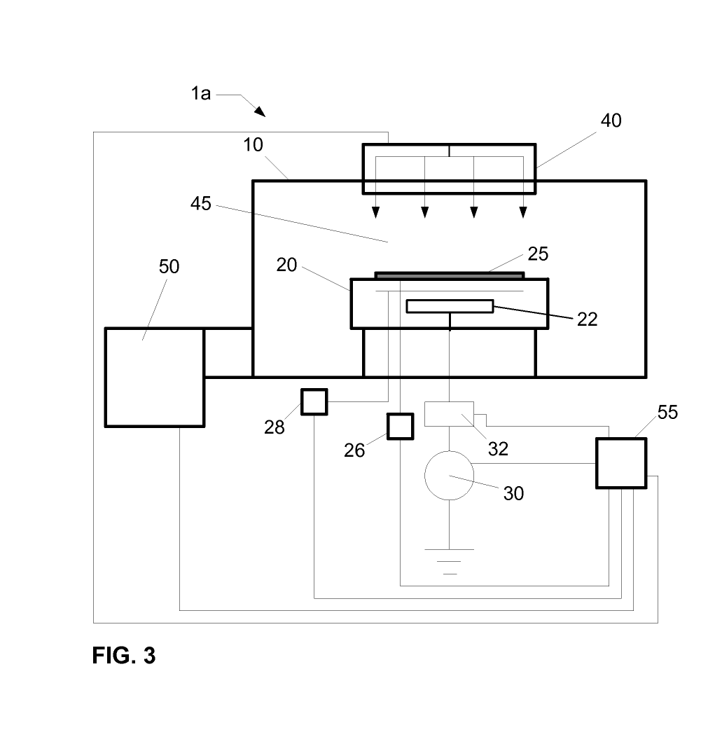

According to one embodiment, a processing system 1a configured to perform the above identified process conditions is depicted in FIG. 3 comprising a plasma processing chamber 10, substrate holder 20, upon which a substrate 25 to be processed is affixed, and vacuum pumping system 50. Substrate 25 can be a semiconductor substrate, a wafer, a flat panel display, or a liquid crystal display. Plasma processing chamber 10 can be configured to facilitate the generation of plasma in processing region 45 in the vicinity of a surface of substrate 25. An ionizable gas or mixture of process gases is introduced via a gas distribution system 40. For a given flow of process gas, the process pressure is adjusted using the vacuum pumping system 50. Plasma can be utilized to create materials specific to a pre-determined materials process, and/or to aid the removal of material from the exposed surfaces of substrate 25. The plasma processing system 1a can be configured to process substrates of any desired size, such as 200 mm substrates, 300 mm substrates, or larger.

Substrate 25 can be affixed to the substrate holder 20 via a clamping system 28, such as a mechanical clamping system or an electrical clamping system (e.g., an electrostatic clamping system). Furthermore, substrate holder 20 can include a heating system (not shown) or a cooling system (not shown) that is configured to adjust and/or control the temperature of substrate holder 20 and substrate 25. The heating system or cooling system may comprise a re-circulating flow of heat transfer fluid that receives heat from substrate holder 20 and transfers heat to a heat exchanger system (not shown) when cooling, or transfers heat from the heat exchanger system to substrate holder 20 when heating. In other embodiments, heating/cooling elements, such as resistive heating elements, or thermo-electric heaters/coolers can be included in the substrate holder 20, as well as the chamber wall of the plasma processing chamber 10 and any other component within the processing system 1a.

Additionally, a heat transfer gas can be delivered to the backside of substrate 25 via a backside gas supply system 26 in order to improve the gas-gap thermal conductance between substrate 25 and substrate holder 20. Such a system can be utilized when temperature control of the substrate is required at elevated or reduced temperatures. For example, the backside gas supply system can comprise a two-zone gas distribution system, wherein the helium gas-gap pressure can be independently varied between the center and the edge of substrate 25.

In the embodiment shown in FIG. 3, substrate holder 20 can comprise an electrode 22 through which RF power is coupled to the processing plasma in processing region 45. For example, substrate holder 20 can be electrically biased at a RF voltage via the transmission of RF power from a RF generator 30 through an optional impedance match network 32 to substrate holder 20. The RF bias can serve to heat electrons to form and maintain plasma. In this configuration, the system can operate as a reactive ion etch (RIE) reactor, wherein the chamber and an upper gas injection electrode serve as ground surfaces. A typical frequency for the RF bias can range from about 0.1 MHz to about 100 MHz. RF systems for plasma processing are well known to those skilled in the art.

Alternately, RF power is applied to the substrate holder electrode at multiple frequencies. Furthermore, impedance match network 32 can improve the transfer of RF power to plasma in plasma processing chamber 10 by reducing the reflected power. Match network topologies (e.g. L-type, π-type, T-type, etc.) and automatic control methods are well known to those skilled in the art.

Gas distribution system 40 may comprise a showerhead design for introducing a mixture of process gases. Alternatively, gas distribution system 40 may comprise a multi-zone showerhead design for introducing a mixture of process gases and adjusting the distribution of the mixture of process gases above substrate 25. For example, the multi-zone showerhead design may be configured to adjust the process gas flow or composition to a substantially peripheral region above substrate 25 relative to the amount of process gas flow or composition to a substantially central region above substrate 25.

Vacuum pumping system 50 can include a turbo-molecular vacuum pump (TMP) capable of a pumping speed up to about 5000 liters per second (and greater) and a gate valve for throttling the chamber pressure. In conventional plasma processing devices utilized for dry plasma etch, a 1000 to 3000 liter per second TMP can be employed. TMPs are useful for low pressure processing, typically less than about 50 mtorr. For high pressure processing (i.e., greater than about 100 mtorr), a mechanical booster pump and dry roughing pump can be used. Furthermore, a device for monitoring chamber pressure (not shown) can be coupled to the plasma processing chamber 10. The pressure measuring device can be, for example, a Type 628B Baratron absolute capacitance manometer commercially available from MKS Instruments, Inc. (Andover, Mass.).

Controller 55 comprises a microprocessor, memory, and a digital I/O port capable of generating control voltages sufficient to communicate and activate inputs to plasma processing system 1a as well as monitor outputs from plasma processing system 1a. Moreover, controller 55 can be coupled to and can exchange information with RF generator 30, impedance match network 32, the gas distribution system 40, vacuum pumping system 50, as well as the substrate heating/cooling system (not shown), the backside gas delivery system 26, and/or the electrostatic clamping system 28. For example, a program stored in the memory can be utilized to activate the inputs to the aforementioned components of plasma processing system 1a according to a process recipe in order to perform a plasma assisted process on substrate 25.

Controller 55 can be locally located relative to the processing system 1a, or it can be remotely located relative to the processing system 1a. For example, controller 55 can exchange data with processing system 1a using a direct connection, an intranet, and/or the internet. Controller 55 can be coupled to an intranet at, for example, a customer site (i.e., a device maker, etc.), or it can be coupled to an intranet at, for example, a vendor site (i.e., an equipment manufacturer). Alternatively or additionally, controller 55 can be coupled to the internet. Furthermore, another computer (i.e., controller, server, etc.) can access controller 55 to exchange data via a direct connection, an intranet, and/or the internet.

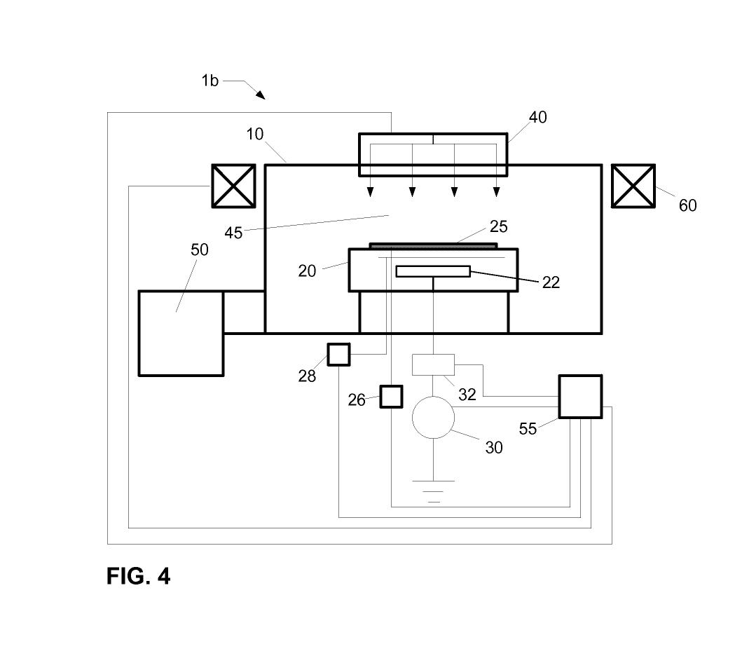

In the embodiment shown in FIG. 4, processing system 1b can be similar to the embodiment of FIG. 3 and further comprise either a stationary, or mechanically or electrically rotating magnetic field system 60, in order to potentially increase plasma density and/or improve plasma processing uniformity, in addition to those components described with reference to FIG. 3. Moreover, controller 55 can be coupled to magnetic field system 60 in order to regulate the speed of rotation and field strength. The design and implementation of a rotating magnetic field is well known to those skilled in the art.

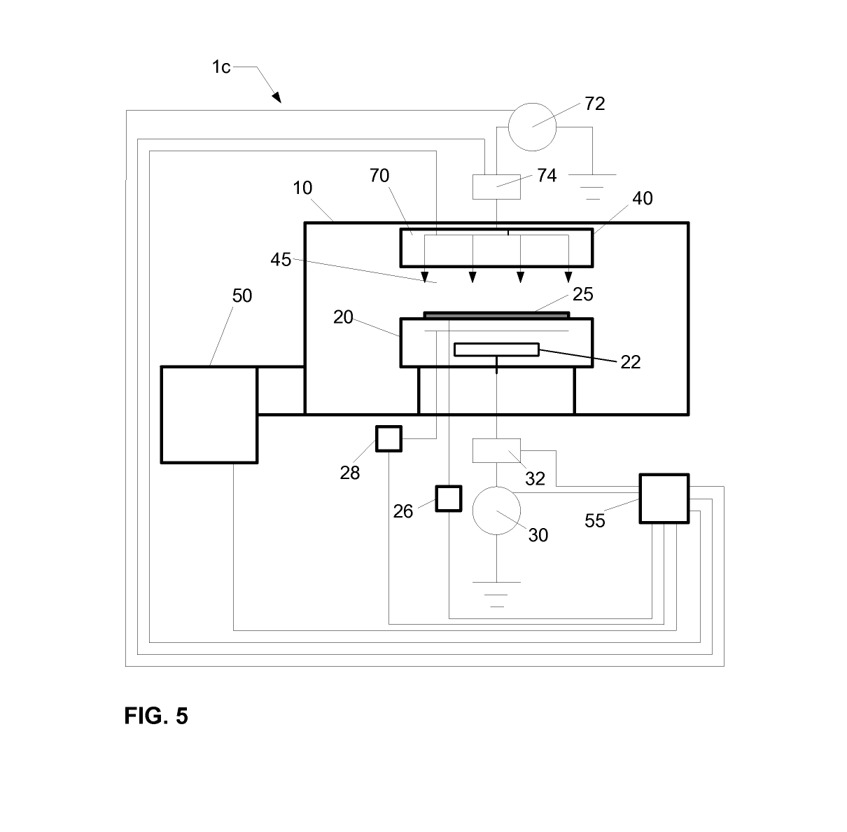

In the embodiment shown in FIG. 5, processing system 1c can be similar to the embodiment of FIG. 3 or FIG. 4, and can further comprise an upper electrode 70 to which RF power can be coupled from RF generator 72 through optional impedance match network 74. A frequency for the application of RF power to the upper electrode can range from about 0.1 MHz to about 200 MHz. Additionally, a frequency for the application of power to the lower electrode can range from about 0.1 MHz to about 100 MHz. Moreover, controller 55 is coupled to RF generator 72 and impedance match network 74 in order to control the application of RF power to upper electrode 70. The design and implementation of an upper electrode is well known to those skilled in the art. The upper electrode 70 and the gas distribution system 40 can be designed within the same chamber assembly, as shown.

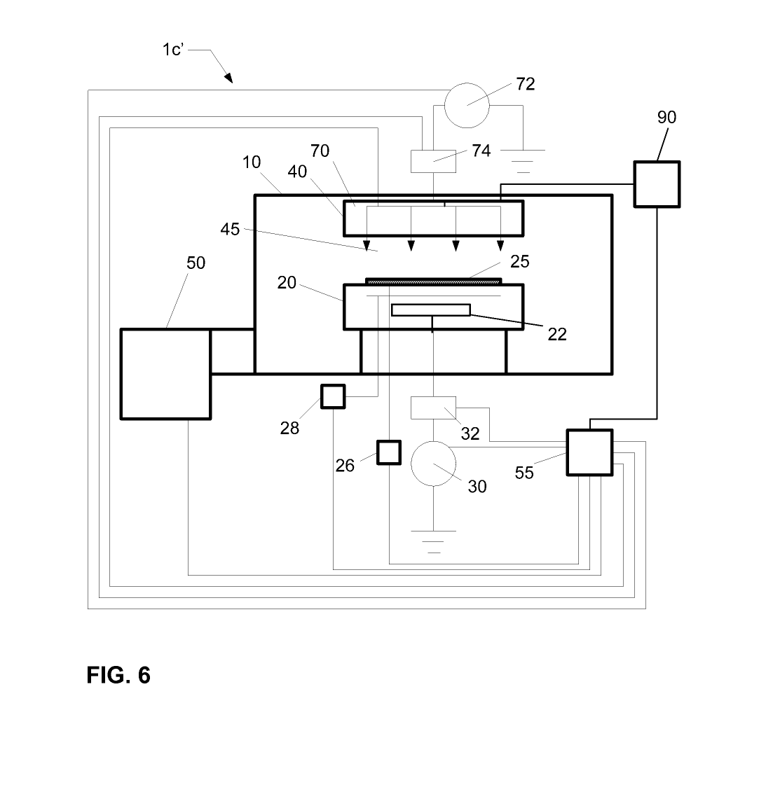

In the embodiment shown in FIG. 6, processing system 1c can be similar to the embodiment of FIG. 5, and can further comprise a direct current (DC) power supply 90 coupled to the upper electrode 70 opposing substrate 25. The upper electrode 70 may comprise an electrode plate. The electrode plate may comprise a silicon-containing electrode plate. Moreover, the electrode plate may comprise a doped silicon electrode plate. The DC power supply 90 can include a variable DC power supply. Additionally, the DC power supply can include a bipolar DC power supply. The DC power supply 90 can further include a system configured to perform at least one of monitoring adjusting, or controlling the polarity, current, voltage, or on/off state of the DC power supply 90. Once plasma is formed, the DC power supply 90 facilitates the formation of a ballistic electron beam. An electrical filter (not shown) may be utilized to de-couple RF power from the DC power supply 90.

For example, the DC voltage applied to upper electrode 70 by DC power supply 90 may range from approximately −2000 volts (V) to approximately 1000 V. Desirably, the absolute value of the DC voltage has a value equal to or greater than approximately 100 V, and more desirably, the absolute value of the DC voltage has a value equal to or greater than approximately 500 V. Additionally, it is desirable that the DC voltage has a negative polarity. Furthermore, it is desirable that the DC voltage is a negative voltage having an absolute value greater than the self-bias voltage generated on a surface of the upper electrode 70. The surface of the upper electrode 70 facing the substrate holder 20 may be comprised of a silicon-containing material.

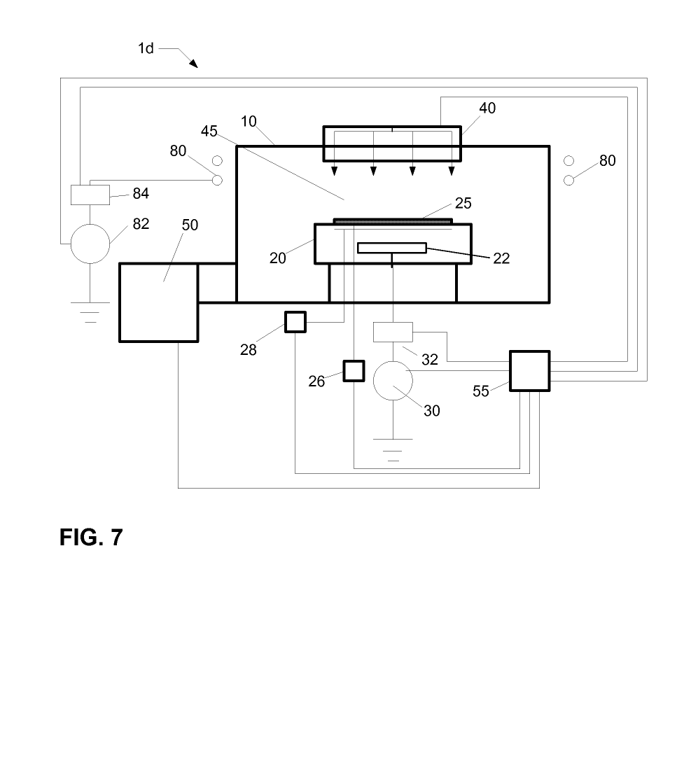

In the embodiment shown in FIG. 7, the processing system 1d can be similar to the embodiments of FIGS. 3 and 4, and can further comprise an inductive coil 80 to which RF power is coupled via RF generator 82 through optional impedance match network 84. RF power is inductively coupled from inductive coil 80 through a dielectric window (not shown) to plasma processing region 45. A frequency for the application of RF power to the inductive coil 80 can range from about 10 MHz to about 100 MHz. Similarly, a frequency for the application of power to the chuck electrode can range from about 0.1 MHz to about 100 MHz. In addition, a slotted Faraday shield (not shown) can be employed to reduce capacitive coupling between the inductive coil 80 and plasma in the processing region 45. Moreover, controller 55 can be coupled to RF generator 82 and impedance match network 84 in order to control the application of power to inductive coil 80.

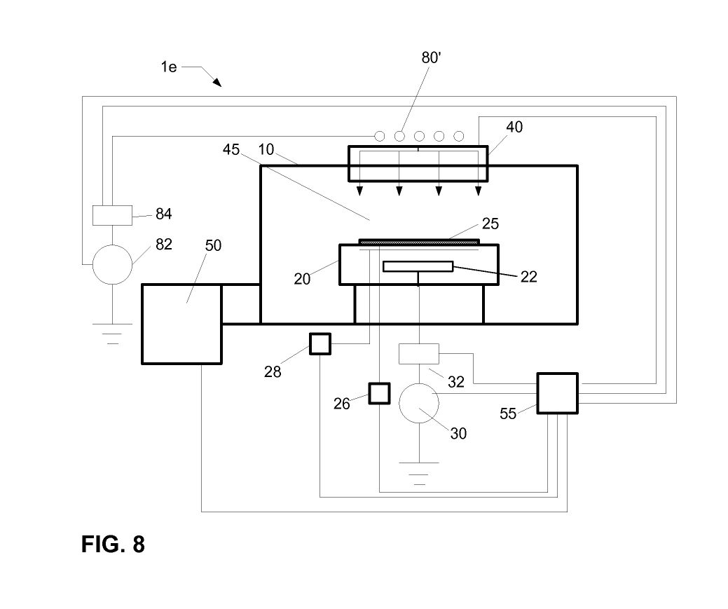

In an alternate embodiment, as shown in FIG. 8, the processing system 1e can be similar to the embodiment of FIG. 7, and can further comprise an inductive coil 80′ that is a “spiral” coil or “pancake” coil in communication with the plasma processing region 45 from above as in a transformer coupled plasma (TCP) reactor. The design and implementation of an inductively coupled plasma (ICP) source, or transformer coupled plasma (TCP) source, is well known to those skilled in the art.

Alternately, the plasma can be formed using electron cyclotron resonance (ECR). In yet another embodiment, the plasma is formed from the launching of a Helicon wave. In yet another embodiment, the plasma is formed from a propagating surface wave. Each plasma source described above is well known to those skilled in the art.

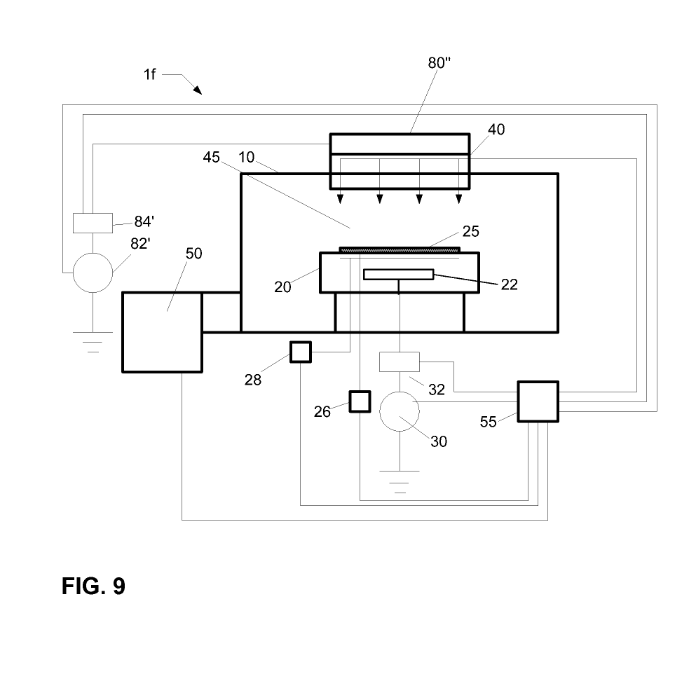

In the embodiment shown in FIG. 9, the processing system 1f can be similar to the embodiments of FIGS. 3 and 4, and can further comprise a surface wave plasma (SWP) source 80″. The SWP source 80″ can comprise a slot antenna, such as a radial line slot antenna (RLSA), to which microwave power is coupled via microwave generator 82′ through optional impedance match network 84′.

In the following discussion, a method of etching a feature in a thin film on a substrate using a multi-layer mask is presented. For example, the processing system for performing dry plasma etching can comprise various elements, such as described in FIGS. 3 through 9, and combinations thereof. Furthermore, for example, the multi-layer mask can comprise a lithographic layer overlying an optional second mask layer, an optional third mask layer, and a hard mask layer.

In one embodiment, a method of transferring a feature pattern to a thin film on a substrate using a hard mask layer is described. The method comprises exposing the substrate to an oxygen-containing flash process after the feature pattern is transferred to the hard mask layer and before the feature pattern is transferred to the thin film. The oxygen-containing flash process comprises a process chemistry having an oxygen-containing gas, such as O₂, CO, CO₂, NO, NO₂, or N₂O, or any combination of two or more thereof. For example, a process parameter space can comprise a chamber pressure of about 5 to about 1000 mtorr, an oxygen-containing gas process gas flow rate ranging from about 1 to about 1000 sccm, an upper electrode (e.g., upper electrode 70 in FIG. 6) RF bias ranging from about 0 to about 2000 W, an upper electrode DC voltage ranging from about 0 V to about −2500 V, and a lower electrode (e.g., electrode 22 in FIG. 6) RF bias ranging from about 10 to about 1000 W. Also, the upper electrode bias frequency can range from about 0.1 MHz to about 200 MHz, e.g., 60 MHz. In addition, the lower electrode bias frequency can range from about 0.1 MHz to about 100 MHz, e.g., 2 MHz.

TABLE 1

| Process | Pressure | UEL Power | LEL Power | DC Voltage | Flow rate (sccm) | | | | | | Time |
|---|---|---|---|---|---|---|---|---|---|---|---|
| step | (mtorr) | (W) | (W) | (V) | CF₄ | CHF₃ | CO₂ | N₂ | C₄F₈ | Ar | (sec) |
| 1 | 100 | 500 | 400 | −500 | 135 | 30 | | | | | 130 |
| 2 | 15 | 1000 | 600 | 0 | | | 400 | 100 | | | 50 |
| 3 | 50 | 0 | 1000 | 0 | | | | | 10 | 1000 | 80 |
| 4 | 15 | 700 | 200 | 0 | | | 300 | | | | |
| 5 | 50 | 900 | 600 | 0 | 250 | | | | | | 30 |
| 6 | 50 | 0 | 600 | 0 | | | 750 | | | | 44 |
| 7 | 100 | 0 | 600 | 0 | | | 750 | | | | 52 |
| 8 | 45 | 1000 | 100 | 0 | 330 | | | | | | 38 |
| 9 | 100 | 0 | 300 | 0 | | | 750 | | | | 10 |

As described earlier, the application of an oxygen-containing flash process to the feature pattern in the hard mask layer prior to transfer of the feature pattern to the underlying thin film causes, among other things, a reduction in RIE lag (i.e., improvement/reduction of micro-loading effect) and reduction in CD bias variation.

In one example, a method of etching a feature pattern in a thin film of low-k dielectric using a silicon oxide (SiOₓ) hard mask layer is provided. Table 1 provides an exemplary series of process recipes, wherein each process step (i.e., steps 1 through 9) recite a chamber pressure (millitorr, mtorr), an upper electrode (UEL) power (watts, W), a lower electrode (LEL) power (watts, W), an upper electrode DC voltage (volts, V), a flow rate (standard cubic centimeters per minute, sccm), and time (seconds, sec).

Other process conditions for each of the process recipes listed in Table 1 include: backside helium gas pressures of 15 torr (center) and 40 torr (edge); UEL temperature (e.g., upper electrode 70 in FIG. 6)=60 degrees C.; and chamber wall temperature=60 degrees C.; and substrate holder temperature (e.g., substrate holder 20 in FIG. 6)=20 degrees C.

TABLE 2

| Process | w/o Flash | w/ Flash |
|---|---|---|
| Parameter | Process | process |
| CD (C/E) (nm) | 89.3/85.9 | 69.8/75.3 |
| LER (C/E) (nm) | 10.6/10.0 | 9.2/8.1 |
| RIE Lag (C/E) (%) | 25.8/21.6 | 9.0/7.3 |
| Pitting (C/E) | Poor | Good |
| Micro-trenching | 42/40 | 16/26 |

In Table 1, process step 1 provides an exemplary recipe for transferring a feature pattern in a lithographic layer to an underlying ARC layer. Process step 2 provides an exemplary recipe for transferring the feature pattern in the ARC layer to an underlying OPL. Process step 3 provides an exemplary recipe for transferring the feature pattern in the OPL to an underlying SiOₓ hard mask layer. Process step 4 provides an exemplary recipe for an oxygen-containing flash process. Process step 5 provides an exemplary recipe for transferring the feature pattern in the SiOₓ hard mask layer to an underlying low-k dielectric layer. Process step 6 provides an exemplary recipe for a first ashing process. Process step 7 provides an exemplary recipe for a second ashing process. Process step 8 provides an exemplary recipe for a liner removal (LRM) process for etching a silicon nitride layer underlying the low-k dielectric layer. Process step 9 provides an exemplary recipe for a de-fluorination cleaning (DFC) process to remove fluorine (F)-containing material from the substrate and the processing system.

Using the process recipes provided in Table 1 with and without the oxygen-containing flash process, several process parameters are provided in Table 2 for the resulting feature pattern in the low-k dielectric. As shown in Table 2, the use of the flash process causes, among other things: (1) a reduction in the CD (nanometers, m) at both center and edge locations (C/E); (2) a reduction in line edge roughness (LER) (nm) at both center and edge locations (C/E); (3) a reduction in RIE lag (%) at both center and edge locations (C/E); (4) a reduction in pitting at both center and edge locations (C/E); and (5) a reduction in micro-trenching. Clearly, Table 2 demonstrates a dramatic reduction in RIE lag when using the flash process.

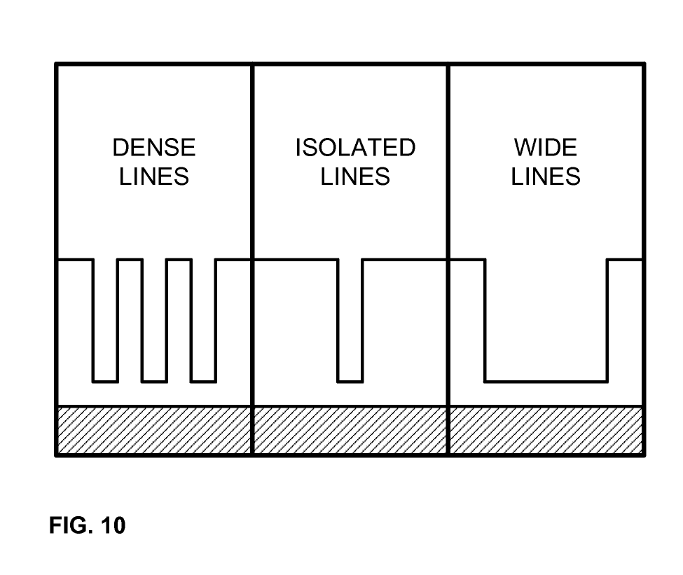

As illustrated in FIG. 10, the geometry and the pattern density of the feature patterns may vary. For example, dense lines (or dense vias/contacts) represent relatively closely spaced features, isolated lines (or isolated vias/contacts) represent relatively widely spaced features, and wide lines (or wide vias/contacts) represent relatively widely spaced features having a relatively wide lateral dimension (i.e., lower aspect ratio feature). The RIE lag (%), provided in Table 2, is calculated as the difference between the etch depth in a wide line and the etch depth in a dense line divided by the etch depth in a dense line (multiplied by 100).

Using the process recipes provided in Table 1 with and without the oxygen-containing flash process, several process parameters at the center and edge of the substrate are provided in Table 3 for the resulting feature pattern in the low-k dielectric. For isolated vias, the etch depth is greater at the edge of the substrate when using the flash process relative to without the flash process. Additionally, for dense vias (e.g., a via chain), the etch depth is greater at the center and edge of the substrate when using the flash process relative to without the flash process.

TABLE 3

| | Center | | Edge | |
|---|---|---|---|---|
| Etch Data | w/o Flash | w/ Flash | w/o Flash | w/ Flash |
| Isolated Via | | | | |
| Depth (nm) | | 236 | 224 | 254 |
| Dense Via (Via Chain) | | | | |
| Depth (nm) | 270 | 317 | 288 | 337 |
| Lag Lines | | | | |
| Mid CD (1x, 2x, 3x) (nm) | 79/95/131 | 81/103/353 | 91/103/133 | 88/111/135 |
| Depth (1x, 2x, 3x) (nm) | 286/325/343 | 321/335/353 | 296/316/329 | 341/357/361 |
| Dense/Isolated Lines | | | | |
| Depth (nm)/Mid CD (nm) | 270/63 248/89 | 300/69 286/75 | 278/69 258/99 | 310/73 294/93 |

Furthermore, for lag lines spaced at one times the line width (1×), two times the line width (2×) and three times the line width (3×), the mid-CD (measured at mid-depth of the feature pattern) (nm) and the etch depth are provided at the center and edge of the substrate with and without the use of the flash process. When the flash process is utilized, the etch depth is greater, and the variation in etch depth between the 1×, 2× and 3× lines is less, hence, indicating the reduction of RIE lag. Further yet, for dense lines and isolated lines, the etch depth and mid-CD are provided at the center and edge of the substrate with and without the use of the flash process. When the flash process is utilized, the etch depth is greater, and the variation in etch depth between dense lines and isolated lines is less, hence, indicating the reduction in RIE lag.

In another example, a method of etching a feature pattern in a thin film of low-k dielectric using a silicon oxide (SiOₓ) hard mask layer is provided. Table 4 provides an exemplary series of process recipes, wherein each process step (i.e., steps 1 through 10) recite a chamber pressure (millitorr, mtorr), an upper electrode (UEL) power (watts, W), a lower electrode (LEL) power (watts, W), an upper electrode DC voltage (volts, V), a flow rate (standard cubic centimeters per minute, sccm), and time (seconds, sec).

TABLE 4

| Process | Pressure | UEL Power | LEL Power | DC Voltage | Flow rate (sccm) | | | | | | | Time |
|---|---|---|---|---|---|---|---|---|---|---|---|---|
| step | (mtorr) | (W) | (W) | (V) | CF₄ | CHF₃ | CO₂ | N₂ | C₄F₈ | Co | Ar | (sec) |
| 1 | 100 | 500 | 400 | −500 | 150 | 20 | | | | | | 115 |
| 2 | 15 | 1000 | 600 | 0 | | | 400 | 100 | | | | 50 |
| 3 | 100 | 0 | 1000 | 0 | | | | | 10 | | 1000 | 59 |
| 4 | 15 | 700 | 200 | 0 | | | 300 | | | | | 15 |
| 5 | 100 | 300 | 500 | 0 | 150 | | | | | | | 35 |
| 6 | 45 | 1000 | 100 | 0 | 330 | 20 | 50 | | | | | 50 |
| 7 | 50 | 0 | 600 | 0 | | | 750 | | | | | 45 |
| 8 | 100 | 0 | 600 | 0 | | | 750 | | | | | 60 |
| 9 | 100 | 0 | 450 | 0 | 50 | 90 | 50 | | | 100 | 400 | 40 |
| 10 | 100 | 0 | 300 | 0 | | | 750 | | | | | 10 |

Other process conditions for each of the process recipes listed in Table 4 include: backside helium gas pressures of 15 torr (center) and 40 torr (edge); UEL temperature (e.g., upper electrode 70 in FIG. 6)=60 degrees C.; and chamber wall temperature=60 degrees C.; and substrate holder temperature (e.g., substrate holder 20 in FIG. 6)=20 degrees C.

In Table 4, process step 1 provides an exemplary recipe for transferring a feature pattern in a lithographic layer to an underlying ARC layer. Process step 2 provides an exemplary recipe for transferring the feature pattern in the ARC layer to an underlying OPL. Process step 3 provides an exemplary recipe for transferring the feature pattern in the OPL to an underlying SiOₓ hard mask layer. Process step 4 provides an exemplary recipe for an oxygen-containing flash process. Process steps 5 and 6 provides an exemplary recipe for transferring the feature pattern in the SiOₓ hard mask layer to an underlying low-k dielectric layer. Process step 7 provides an exemplary recipe for a first ashing process. Process step 8 provides an exemplary recipe for a second ashing process. Process step 9 provides an exemplary recipe for a LRM process. Process step 10 provides an exemplary recipe for a DFC process.

TABLE 5

| | 0.14 micron | 0.14 micron | | | CD Bias |
|---|---|---|---|---|---|
| | Dense Line | Isolated Line | 2x Line | 3x Line | Delta (%) |
| w/o Flash Process | | | | | |
| Center CD/LER (nm) | 82.8/6.6 | 88.6/4.9 | 144.1/8.4 | 264.6/6.8 | 23.8 |
| Edge CD/LER (nm) | 89.6/6.8 | 96.7/5.6 | 151.3/4.7 | 269.8/5.6 | 23.4 |
| C-E Mid-CD delta (nm) | 7.3 | 8.1 | 7.2 | 5.3 | |
| w/ Flash Process | | | | | |
| Center CD/LER (nm) | 91.9/4.4 | 102/4 | 177/4.8 | 302.4/4.8 | 17.2 |
| Edge CD/LER (nm) | 104.1/5.7 | 112.1/4.5 | 195.4/4.5 | 324.8/4.9 | 15 |
| C-E Mid-CD delta (nm) | 12.2 | 10.1 | 18.4 | 22.4 | |

Using the process recipes provided in Table 4 with and without the oxygen-containing flash process, several process parameters at the center and edge of the substrate are provided in Table 5 for the resulting feature pattern in the low-k dielectric. Table 5 provides the center and edge CD and LER with and without the flash process for 0.14 micron dense lines, 0.14 micron isolated lines, 2× lines, and 3× lines. Additionally, Table 5 provides the difference in the CD between center and edge locations on the substrate (C-E Mid-CD delta) for processes with and without the flash process. Further, Table 5 provides the CD bias delta (%) at the center and edge of the substrate for processes with and without the flash process. The CD bias delta (%) is calculated as the difference between the initial CD for dense lines and the final CD for dense lines divided by the difference between the initial CD for wide lines and the final CD for wide lines (multiplied by 100).

As observed in Table 5, the LER is reduced at both the center and edge of the substrate when the flash process. Further, as observed in Table 5, the CD bias delta is substantially reduced at both the center and the edge of the substrate when the flash process is used.

Although only certain embodiments of this invention have been described in detail above, those skilled in the art will readily appreciate that many modifications are possible in the embodiments without materially departing from the novel teachings and advantages of this invention. Accordingly, all such modifications are intended to be included within the scope of this invention.

1. A method of transferring a pattern to a substrate, comprising:
disposing a substrate comprising a multi-layer mask overlying a thin film in a plasma processing system, wherein said multi-layer mask comprises at least a lithographic layer and a hard mask layer;
forming a feature pattern in said lithographic layer using a lithographic process;
transferring said feature pattern in said lithographic layer to the remaining layers of said multi-layer mask including said hard mask layer using one or more etching processes;
exposing said feature pattern in said hard mask layer to an oxygen-containing flash process in order to remove residue from said feature pattern formed during said transferring of said feature pattern to said hard mask layer; and
transferring said feature pattern in said hard mask layer to said thin film following said exposing of said feature pattern in said hard mask layer to said oxygen-containing flash process.

2. The method of claim 1, wherein said exposing said feature pattern to said oxygen-containing flash process comprises:
introducing an oxygen-containing gas to said plasma processing system;
setting a flash chamber pressure in said plasma processing system; and
forming plasma from said oxygen-containing gas.

3. The method of claim 2, wherein said oxygen-containing gas comprises O₂, CO, CO₂, NO, NO₂, or N₂O, or any combination of two or more thereof.

4. The method of claim 2, wherein said oxygen-containing gas consists of CO₂.

5. The method of claim 2, further comprising:
introducing a noble gas to said plasma processing system.

6. The method of claim 2, wherein said setting said flash chamber pressure comprises setting a pressure ranging from about 10 mtorr to about 20 mtorr.

7. The method of claim 2, further comprising:
setting a first power level for a first radio frequency (RF) signal applied to a lower electrode within a substrate holder for supporting said substrate; and
setting a second power level for a second RF signal applied to an upper electrode opposing said lower electrode above said substrate.

8. The method of claim 1, wherein said multi-layer mask comprises said lithographic layer overlying an anti-reflective coating (ARC) layer overlying an organic planarization layer (OPL) overlying said hard mask layer.

9. The method of claim 1, wherein said lithographic layer comprises a layer of radiation-sensitive material.

10. The method of claim 1, wherein said hard mask layer comprises silicon oxide (SiOₓ).

11. The method of claim 10, wherein said transferring said feature pattern to said hard mask layer comprises selectively etching said hard mask layer relative to said underlying thin film using a polymerizing process chemistry.

12. The method of claim 11, wherein said using said polymerizing process chemistry comprises:
introducing a process gas comprising at least one CₓF_{y}H_{z}-containing gas wherein x and y are integers greater than or equal to unity and z is an integer greater than or equal to zero;
setting a chamber pressure in said plasma processing system; and
forming plasma from said process gas.

13. The method of claim 12, wherein said process gas comprises C₄F₈ and Ar.

14. The method of claim 1, wherein said thin film comprises a dielectric material.

15. The method of claim 1, wherein said thin film comprises a porous dielectric material, a non-porous dielectric material, a low dielectric constant (low-k) dielectric material, or an ultra low-k dielectric material, or any combination of two or more thereof.

16. The method of claim 1, wherein said feature pattern formed in said thin film comprises a trench-via structure for forming a metal interconnect.

17. The method of claim 1, further comprising:
performing a first ashing process on said substrate, wherein said first ashing process comprises using a CO₂-based plasma at a pressure less than about 75 mtorr; and
performing a second ashing process on said substrate, wherein said second ashing process comprises using a CO₂-based plasma at a pressure less than about 75 mtorr;

18. The method of claim 1, further comprising:
reducing a critical dimension (CD) from an initial CD in said lithographic layer to a final CD in said thin film.

19. A method for transferring a feature pattern to a thin film on a substrate using a hard mask layer, comprising:
exposing said substrate to an oxygen-containing flash process after said feature pattern is transferred to said hard mask layer and before said feature pattern is transferred to said thin film.

20. A computer readable medium containing program instructions for execution on a plasma processing system, which when executed by the plasma processing system, cause the plasma processing system to perform the steps of:
transferring a feature pattern to a thin film on a substrate using a hard mask layer; and
exposing said substrate to an oxygen-containing flash process after said feature pattern is transferred to said hard mask layer and before said feature pattern is transferred to said thin film.
